(19) United States
(12) Patent Application Publication
(10) Pub. No.: US 2019/0187003 A1
(43) Pub. Date: Jun. 20, 2019

(54) Corrosion-Resistant Temperature Sensor Probe

(71) Applicant: Lam Research Corporation, Fremont, CA (US)

(72) Inventors: Justin Brunnett, Pleasanton, CA (US); Shawn Tokairin, Fremont, CA (US); Shijian Li, San Jose, CA (US); Darrell Ehrlich, San Jose, CA (US)

(21) Appl. No.: 15/842,763

(22) Filed: Dec. 14, 2017

(51) Int. Cl. G01K 1/10; H01J 37/32

(52) U.S. Cl. CPC G01K 1/10; G01K 7/02; H01J 37/32477; H01J 37/32935

(57) ABSTRACT

A temperature sensor probe having a shaft is described. The shaft is made from a material that is corrosion resistant to plasma and remnants of a plasma process. The shaft extends over a portion of a metal layer, which forms a tip of the temperature sensor probe. The shaft further extends over a sleeve of the temperature sensor probe, a portion of a fiber optic medium of the temperature sensor probe and a portion of the fiber bundle housing of the temperature sensor probe. The material of the shaft increases a number of active processing hours for which the shaft is used within a plasma chamber during the plasma process.

### FIELD

The present embodiments relate to a corrosion-resistant temperature sensor probe.

### Background

In some plasma processing systems, a processing gas is supplied to a space within a plasma chamber to process a wafer. The wafer is placed on a support to perform various processes, such as cleaning, depositing, etching, sputtering, etc. During the processing of the wafer, it is important that a temperature within the plasma chamber be maintained.

It is in this context that embodiments described in the present disclosure arise.

### SUMMARY

Embodiments of the disclosure provide systems, apparatus, methods and computer programs for fabricating and using a corrosion-resistant temperature sensor probe. It should be appreciated that the present embodiments can be implemented in numerous ways, e.g., a process, an apparatus, a system, a device, or a method on a computer readable medium. Several embodiments are described below.

A temperature sensing device usually corrodes when exposed to chemistries used in forming plasma. This corrosion causes premature failure of the temperature sensing device. The premature failure of the temperature sensing device leads to an increased frequency of replacement of the temperature sensing device and to increased down time of a plasma processing chamber. The down time is increased when the plasma processing chamber is opened to replace the temperature sensing device. The plasma processing chamber cannot be used until the plasma processing chamber is closed. Additionally, the temperature sensing device has a filler, such as titanium dioxide used as a pigment. When a portion of the temperature sensing device corrodes, the filler mixes with fluorine within the plasma processing chamber to form a powder, such as titanium fluoride. Remains of the powder within the plasma processing chamber causes contaminant particle issues inside the plasma processing chamber to negatively affect processing of the wafer.

In some embodiments, a shaft, such as a plasma resistant or a chemical resistant shaft, is described to allow the use of a temperature sensor probe inside a plasma chamber. The shaft of the temperature sensor probe is made from a material, such as a chemical resistant or a plasma resistant material. Examples of the material for the shaft include perfluoroalkoxy (PFA), polytetrafluoroethylene (PTFE), zirconia, ceramic, mullite, steatite, cordierite, or a combination thereof. The material offers protection against corrosion of the shaft and maintains a low thermal conductivity to provide an accurate temperature reading.

By using the material that has a high chemical corrosion resistance, a life of a temperature sensor probe is extended. PTFE and PFA contain fluorine in their chemical structures. Due to the presence of fluorine within the chemical structures, the shaft made from PTFE or PFA or a combination thereof tends to have a higher resistance to fluorine based etching gases. PTFE or PFA of a combination thereof is more susceptible to corrosion from oxygen based etching gases compared to the fluorine based etching gases. However, the oxygen based etching gases are applied in a lower number of processing operations compared to a number of processing operations in which the fluorine based etching gases are applied. For example, a number of active processing hours in which the oxygen based etching gases are applied to a gap within the plasma chamber is less than a number of active processing hours in which fluorine based etching gases are applied to the gap for processing a substrate. As such, a lifetime of the temperature sensor probe is drastically improved.

Zirconia is a type of ceramic material, and the chemical bonds of zirconia are extremely high energy. Therefore, the shaft that is made from zirconia exhibits virtually non-existent corrosion from fluorine based etching gases and oxygen based etching gases when a top portion of the shaft is inserted into a ring to be surrounded by the ring. The ring may be an edge ring or a tunable edge ring. The material listed has sufficiently low thermal conductivity to deliver an accurate temperature reading of temperature of the edge ring or the tunable edge ring. If the thermal conductivity of the temperature sensor probe is too high, such as that of most ceramics and metals, the shaft will conduct heat out of the edge ring itself or a thermally conductive layer of the temperature sensor probe where the temperature is measured and will lower the temperature read by the temperature sensor probe. This reduction in sensed temperature leads to a reduction in accuracy of the output of the temperature sensor probe.

Some advantages of the herein described systems and methods include providing the temperature sensor probe that lasts greater than a pre-determined time period, such as greater than about 4 months, or about 6 months, or about 1 year, or about 1 year and 2 months, or about 1 year and 4 months, thus reducing a down time of the plasma processing chamber and lowering the frequency with which the temperature sensing device is replaced. For example, the temperature sensor probe is useable for greater than about 1500 active processing hours. As another example, the temperature sensor probe is useable for greater than about 1450 active processing hours. The material also has a low thermal conductivity and so provides an accurate temperature reading. Additionally, the material reduces chances of, such as eliminates or avoids, production of chemical byproducts, such as titanium fluoride powder, inside the plasma chamber. These chemical byproducts act as contaminants to the plasma processing chamber and reduce its efficiency.

Further advantages of temperature sensor probe include providing an extended feature between a thermally conductive layer of the temperature sensor probe and the shaft. The extended feature generates a retention force that retains the thermally conductive layer between the shaft and a sleeve of the temperature sensor probe.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1A is a diagram of an embodiment of system to illustrate a manner of making and using a corrosion-resistant temperature sensor probe.

FIG. 1B is a diagram of an embodiment of the temperature sensor probe.

FIG. 2 is a diagram of an embodiment of a portion of the temperature sensor probe.

FIG. 3A is a diagram of an embodiment of a portion of the temperature sensor probe to illustrate an extended feature.

FIG. 3B is a diagram of an embodiment of a plasma chamber to illustrate a cross-section of the temperature sensor probe.

FIG. 3C is a cross-section of an embodiment of a portion of the temperature sensor probe.

FIG. 3D is a cross-section of an embodiment of a portion of the temperature sensor probe.

FIG. 4A is a diagram of an embodiment of a system to illustrate use of the temperature sensor probe in contact with a tunable edge ring of a plasma chamber.

FIG. 4B is a diagram of an embodiment of a system to illustrate use of the temperature sensor probe in contact with an edge ring of the plasma chamber.

### DETAILED DESCRIPTION

The following embodiments describe systems and methods for fabricating and using a corrision-resistant temperature sensor probe. It will be apparent that the present embodiments may be practiced without some or all of these specific details. In other instances, well known process operations have not been described in detail in order not to unnecessarily obscure the present embodiments.

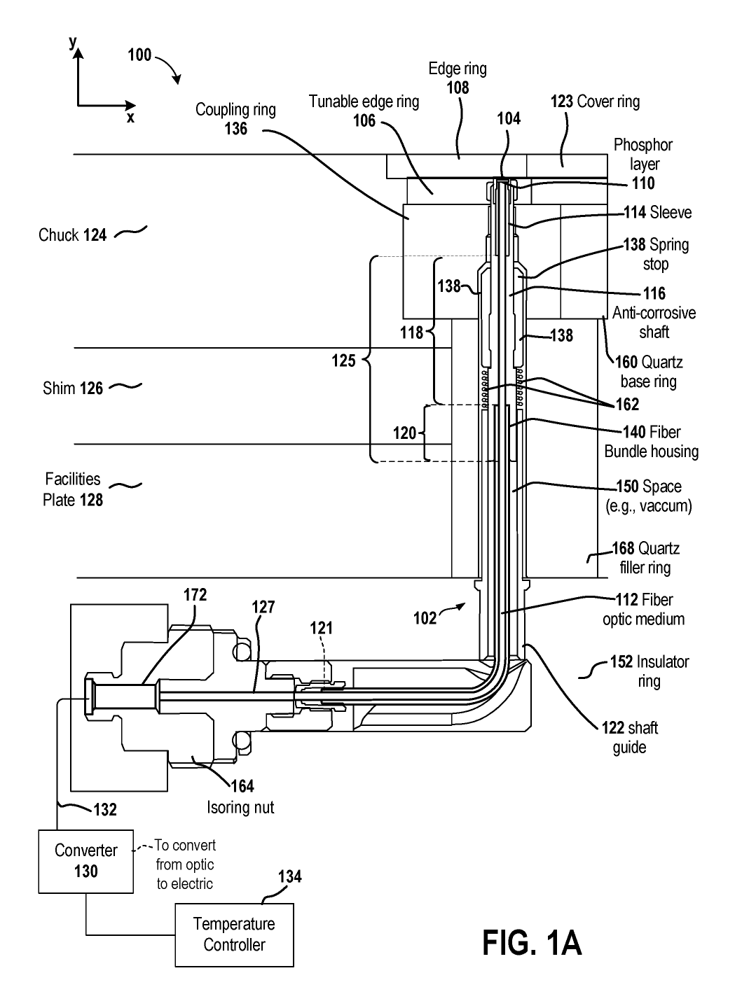

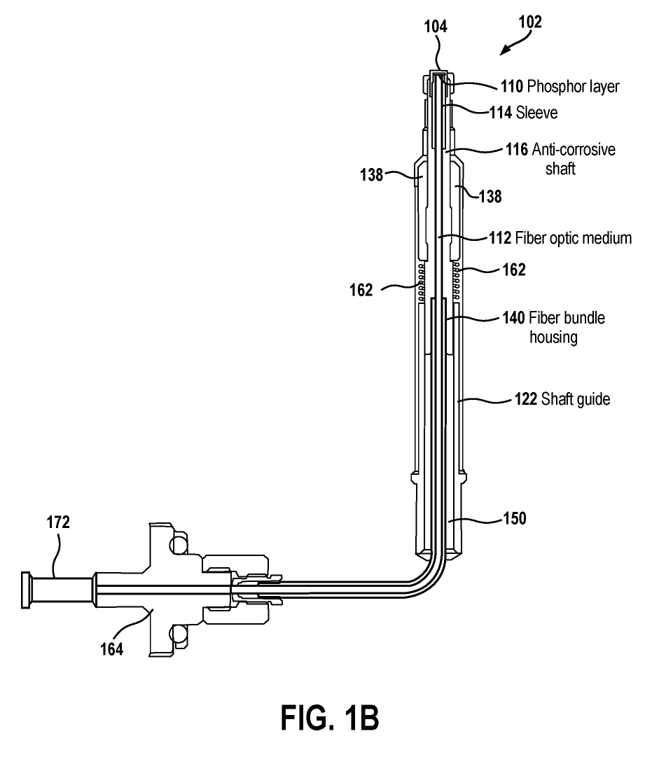

FIG. 1A is a diagram of an embodiment of a system 100 to illustrate a manner of making and using a corrision-resistant temperature sensor probe 102. The system 100 includes the temperature sensor probe 102, a chuck 124, an edge ring 108, a tunable edge ring 106, a cover ring 123, a coupling ring 136, a base ring 160, a filler ring 168, an insulator ring 152, a facilities plate 128, a shim 126, a converter 130, and a temperature controller 134. The chuck 124 is an example of a substrate support. Each of the chuck 124, the edge ring 108, the tunable edge ring 106, the cover ring 123, the coupling ring 136, the base ring 160, the filler ring 168, the insulator ring 152, the facilities plate 128, and the shim 126 is an example of a structure within a plasma chamber.

An example of the chuck 124 includes an electrostatic chuck. The edge ring 108 is made of a conductive material, such as silicon, boron doped single crystalline silicon, alumina, silicon carbide, or silicon carbide layer on top of alumina layer, or an alloy of silicon, or a combination thereof. Moreover, the tunable edge ring 106 is made from a dielectric material, such as quartz, or ceramic, or a polymer. Furthermore, each coupling ring 136 and 152 is made from the dielectric material. Also, each of the base ring 160 and the filler ring 168 is fabricated from the dielectric material, such as quartz. The cover ring 123 is made from the dielectric material. Various facility components are coupled to the facilities plate 128, such as components for heating the chuck 124, cooling the chuck 124, control of lift pins for lifting a substrate placed on a top surface of the chuck 124, and electrostatic clamping of the substrate to the chuck 124. The shim 126 is made from a non-conductive material, such as an insulator, or a compliant material.

Examples of the converter 130 include a light to electrical signal converter. To illustrate, the converter 130 is a photo detector, such as one or more photodiodes. As another illustration, the converter 130 includes a photo detector and an amplifier. The photo detector is coupled to the amplifier. As used herein, a controller includes a processing device, such as, a processor, or an application-specific integrated circuit (ASIC), or a programmable logic device (PLD), or a microprocessor. The controller further includes a memory device, e.g., a random access memory (RAM), a read-only memory (ROM), a volatile memory, a non-volatile memory, etc. Examples of the memory device include a Flash memory, a hard disk, etc. The memory device is coupled to the processing device. The converter 130 is coupled to the temperature sensor probe 102 via a temperature probe cable 132, such as a fiber optic cable, that is used to carry light.

The shim 126 is located below the chuck 124 and the facilities plate 128 is located below the shim 126. Moreover, the insulator ring 152 is located below the facilities plate 128. The filler ring 168 is located above the insulator ring 152 and surrounds the facilities plate 128, the shim 126, and a portion of the chuck 124.

Moreover, the coupling ring 136 is located above a portion of the chuck 124, above a portion of the filler ring 168, and surrounds another portion of the chuck 124. The base ring 160 surrounds the coupling ring 136 and is located above a portion of the filler ring 168. The tunable edge ring 106 surrounds a portion of the chuck 124 and is located above a portion of the coupling ring 136. Also, the edge ring 108 surrounds a portion of the chuck 124, is located above the tunable edge ring 106, and is located about a portion of the coupling ring 136.

The base ring 160 surrounds the coupling ring 136 and is located above a portion of the filler ring 168. The cover ring 123 surrounds a portion of the edge ring 108, and is located above a portion of the coupling ring 136 and above the base ring 160. The base ring 160 is coupled to a ground potential.

The temperature sensor probe 102 has a thermally conductive layer 104, a phosphor layer 110, a sleeve 114, a spring stop 138, a shaft 116, a spring 162, a fiber bundle housing 140, a fiber optic medium 112, a shaft guide 122, an isolation (iso) ring nut 164, and a connector 172. The thermally conductive layer 104 is sometimes referred to herein as a thermally conductive cap. The phosphor layer 110 is an example of a luminescent fluoroptic tip or a luminescence layer. Examples of the thermally conductive layer 104 include a high thermally conductive layer made from a material such as aluminum or copper oraluminum nitride, which are resistive to corrosion from plasma within the plasma chamber and from contaminants generated from plasma processes within the plasma chamber. As an example, the thermally conductive layer 104 has a cross-section that has an inverted U-shape. The sleeve 114 is fabricated from an insulator material, such as plastic. Examples of the plastic include polyether ether ketone, also known as PEEK™. The spring stop 138 is made from a metal or plastic. The 162 is fabricated from a metal, such as aluminum or steel or an alloy of aluminum or an alloy of steel. The spring 162 extends to surround a portion of the shaft 116 in a vertical direction and has its length in the vertical direction. The spring stop 138 is situated to surround another portion of the shaft 116 above the spring 162 and has its length in the vertical direction. The fiber bundle housing 140 is a jacket, which is a protective polymer layer, such as a layer made from plastic or polyurethane or poly vinyl chloride (PVC) or polyethylene or a combination of polyethylene and polyethylene terephthalate (PET). Mylar™ is an example of PET. As an example, the fiber bundle housing 140 is in the form of a tape. The fiber optic medium 112 is a bundle of optical fibers that are attached to, such as bonded to or in contact with, the phosphor layer 110. A fiber optic medium is sometimes referred to herein as a temperature signal-carrying medium. To illustrate, the fiber optic medium 112 is adhered to a bottom surface of the phosphor layer 110 via a silicone adhesive. As an example, the fiber optic medium 112 has hundreds, such as 300 or 400, optical fibers for transferring light. The isolation ring nut 164 is made from a plastic. The connector 172 is made from a plastic material. The shaft guide 122 is made from the insulator material, such as plastic. To illustrate, the shaft guide 122 is made from polyetherimide (PEI), such as Ultem™.

The shaft 116 is made from a material that is resistant to corrosion. For example, the shaft 116 is an anti-corrosive shaft. To further illustrate, the shaft 116 is made from perfluoroalkoxy (PFA), polytetrafluoroethylene (PTFE), zirconia, ceramic, quartz, mullite, steatite, or cordierite. PTFE is sometimes referred to herein as Teflon™ and is a synthetic polymer of tetrafluoroethylene. Teflon™ is a brand name of PTFE-based formulas. PTFE is a fluorocarbon solid, as it is a high-molecular-weight compound including carbon and fluorine.

It should be noted that PFA, PTFE, zirconia, mullite, steatite, and cordierite have low thermal conductivity. To illustrate, a thermal conductivity of each of PFA and PTFE is less than 0.5 watt(s) per meter Kelvin (W/m-K). For example, the thermal conductivity of PTFE is about 0.25 W/m-K, such as ranging from and including about 0.2 W/m-K to about 0.3 W/m-K. Moreover, the thermal conductivity of PFA is about 0.25 W/m-K, such as ranging from and including about 0.2 W/m-K to about 0.3 W/m-K. Furthermore, the thermal conductivity of zirconia is about 2.2 W/m-K, such as ranging from and including about 2.1 W/m-K to about 2.3 W/m-K. Also, the thermal conductivity of steatite is about 2.5 W/m-K, such as ranging from and including about 2 W/m-K to about 3 W/m-K. The thermal conductivity of cordierite is about 1.6 W/m-K, such as ranging from and including about 1 W/m-K to about 2 W/m-K. The thermal conductivity of mullite is about 3.5 W/m-K, such as ranging from and including about 3 W/m-K to about 4 W/m-K. The thermal conductivity of a ceramic is about 30 W/m-K, such as ranging from and including about 25 W/m-K to about 35 W/m-K. These values can be compared to a thermal conductivity of alumina, which is about 18 W/m-K or of aluminum, which is about 205 W/m-K. It should be noted that the materials listed above for fabricating the shaft 116 have low thermal conductivity except for ceramic. The low thermal conductivity reduces chances of heat from the thermally conductive layer 104 from being transferred via the shaft 116 to the shaft guide 122 between the fiber bundle housing 140 and the insulator ring 152. The transfer of heat reduces temperature of the thermally conductive layer 104 resulting in inaccurate measurements of temperature measured by the phosphor layer 110. The temperature measured by the phosphor layer 110 represents temperature of the edge ring 108, or the tunable edge ring 106, or a heater embedded within the tunable edge ring 106. Because the materials except for ceramic have low thermal conductivity, the temperature that is measured by the measured by the phosphor layer 110 is accurate. It should be noted that zirconia is a type of ceramic.

All the materials listed above for fabricating the shaft 116 have a high resistance to corrosion by, e.g., are anti-corrosive to, plasma within the plasma chamber or by contaminant materials, which are chemicals left within the plasma chamber after processing a substrate. For example, the materials listed above for fabricating the shaft 116 have a corrosion resistance, such as an etch resistance, to allow the temperature sensor probe 102 to be used for greater than 1500 active processing hours. To illustrate, the temperature sensor probe 102 is useable in the plasma chamber from and including about 1500 active processing hours to about 3000 active processing hours. As another illustration, the temperature sensor probe 102 is useable in the plasma chamber from and including about 1500 active processing hours to about 4000 active processing hours. As another illustration, the temperature sensor probe 102 is useable in the plasma chamber from and including about 1500 active processing hours to about 5500 active processing hours. As yet another illustration, the temperature sensor probe 102 is useable in the plasma chamber from and including about 1500 active processing hours to about 7500 active processing hours. As another illustration, the temperature sensor probe 102 is useable in the plasma chamber from and including about 3000 active processing hours to about 7500 active processing hours.

As another example, the materials listed above for fabricating the shaft 116 have an etch resistance to allow the temperature sensor probe 102 to be used for greater than 2000 active processing hours. To illustrate, the temperature sensor probe 102 is useable in the plasma chamber from and including about 2100 active processing hours to about 3000 active processing hours. As another illustration, the temperature sensor probe 102 is useable in the plasma chamber from and including about 2100 active processing hours to about 4000 active processing hours. As another illustration, the temperature sensor probe 102 is useable in the plasma chamber from and including about 2100 active processing hours to about 5500 active processing hours. As yet another illustration, the temperature sensor probe 102 is useable in the plasma chamber from and including about 2100 active processing hours to about 7500 active processing hours. As another illustration, the temperature sensor probe 102 is useable in the plasma chamber from and including about 2100 active processing hours to about 7500 active processing hours.

As another example, the materials listed above to make the shaft 116 have the etch resistance such that the temperature sensor probe 102 is used within the plasma chamber in which the system 100 is located for greater than about 5000 active processing hours. To illustrate, the materials listed above to make the shaft 116 have the etch resistance such that the temperature sensor probe 102 is used within the plasma chamber for a time period from and including about 5000 active processing hours to about 7500 active processing hours. As another illustration, the temperature sensor probe 102 is useable in the plasma chamber from and including about 5000 active processing hours to about 7500 active processing hours. As another illustration, the temperature sensor probe 102 is useable in the plasma chamber from and including about 5000 active processing hours to about 8500 active processing hours. As yet another illustration, the temperature sensor probe 102 is useable in the plasma chamber from and including about 5000 active processing hours to about 10,000 active processing hours.

As an example, an RF hour, described herein, is a time period of an hour during which the substrate is processed using plasma within the plasma chamber. The substrate is processed using one or more process gases, such as fluorine, oxygen, fluorine containing gas, or oxygen containing gas, etc. It should be noted that active processing hours that are greater than about 5000 active processing hours allow the temperature sensor probe 102 to be used for greater than a year. Moreover, the active processing hours that are between about 1500 to about 2000 active processing hours allow the temperature sensor probe 102 to be used from about 3 months to about 4 months.

The thermally conductive layer 104 is a cylinder that has a tip at one end that is closed and an opening at an opposite end. The thermally conductive layer 104 is in contact with the tunable edge ring 106. For example, the thermally conductive layer 104 is inserted into a slot formed in a bottom surface of the tunable edge ring 106 and at least a portion of the thermally conductive layer 104 is located within the slot. The thermally conductive layer 104 surrounds the phosphor layer 110 and a portion of the sleeve 114. The phosphor layer 110 lies within the opening of the thermally conductive layer 104 and is contact with an inside surface of the tip of the thermally conductive layer 104. The thermally conductive layer 104 is oriented along the vertical direction, which is a direction of a y-axis. The phosphor layer 110 is oriented along a horizontal direction, which is a direction of an x-axis.

Moreover, the sleeve 114 is a tube that is located below the phosphor layer 110 and surrounds a portion of the fiber optic medium 112. The sleeve 114 extends over the fiber optic medium 112 in the vertical direction to surround the portion of the fiber optic medium. The sleeve 114 has the portion that is located inside the opening of the thermally conductive layer 104 and another portion located outside the opening of the thermally conductive layer 104. The sleeve 114 has the portion that is surrounded by the thermally conductive layer 104 and has another portion that is surrounded by the shaft 116. The sleeve 114 is oriented along the vertical direction.

The shaft 116 is a tube that surrounds a portion of the thermally conductive layer 104, a portion of the sleeve 114, a portion 118 of the fiber optic medium 112, and a portion 120 of the fiber bundle housing 140. For example, the shaft 116 extends in the vertical direction along the portion of the thermally conductive layer 104, the portion of the sleeve 114, the portion 118 of the fiber optic medium 112, and the portion 120 of the fiber bundle housing 140. The portion 118 of the fiber optic medium 112 extends in the vertical direction from the sleeve 114 to the fiber bundle housing 140. The shaft 116 extends in the vertical direction over the portion 118 of the fiber optic medium 112 to protect the fiber optic medium 112 from being corroded by the one or more process gases. For example, a portion of the shaft 116 is adjacent to the portion 118 of the fiber optic medium 112. The shaft 116 is surrounded partially by the spring stop 138, partially by the spring 162, and partially by the shaft guide 122. The shaft 116 is located below the phosphor layer 110. The portion 120 extends from a level below the springs 162 until a bottom surface of the shaft 116 or until a space 150 between the fiber bundle housing 140 and the shaft guide 122. The level above the springs 162 is below the spring stop 138.

The shaft 116 surrounds a portion 125 of the fiber optic medium 112 along the vertical direction. The portion 125 extends in the vertical direction from the bottom surface of the sleeve 114 to the space 150. The portion 125 of the fiber optic medium 112 is not surrounded by the sleeve 114 in the vertical direction and is located below and adjacent to the sleeve 114.

The spring stop 138 is adjacent to a portion of the shaft 116 and is oriented along the vertical direction. The spring stop 138 is located below the sleeve 114 and above the springs 162. At a bottom of the spring stop 138 is a protrusion extending in the horizontal direction towards the shaft 116 to fit the spring stop 138 to the shaft 116.

The spring 162 is located adjacent to a bottom surface of the spring stop 138. For example, the spring 162 has an upper end that abuts against a lower end of the spring stop 138. The spring 162 has a lower end that abuts an upper surface of the shaft guide 122. Moreover, the spring 162 is oriented in the vertical direction to have a length in the vertical direction. Compression forces within the spring 162 push up in the vertical direction against the spring stop 138 to move up the shaft 116, which is fitted to the thermally conductive layer 104, to further move up the thermally conductive layer 104. The thermally conductive layer 104 moves up in the vertical direction to contact the heater, such as a resistor, located within the tunable edge ring 106 or the edge ring 108.

The fiber bundle housing 140 has a vertical linear portion extending in the vertical direction, and the vertical linear portion of the fiber bundle housing 140 is contiguous with a curved portion, such as an arced portion having a radius, of the fiber bundle housing 140. The curved portion of the fiber bundle housing 140 located below the shaft guide 122. The curved portion of the fiber bundle housing 140 is contiguous with a horizontal linear portion of the fiber bundle housing 140. For example, the curved portion of the fiber bundle housing 140 is located between the vertical linear portion of the fiber bundle housing 140 and the horizontal linear portion of the fiber bundle housing 140. The horizontal linear portion of the fiber bundle housing 140 extends along the horizontal direction, which is substantially perpendicular to the vertical direction. For example, the horizontal direction forms an angle ranging from and including 85° to 95° with respect to the vertical direction. As another example, the horizontal direction is perpendicular to the vertical direction. The horizontal linear portion of the fiber bundle housing 140 extends via the isolation ring nut 164 and the connector 172 to couple to the temperature probe cable 132. The vertical linear portion of the fiber bundle housing 140, the curved portion of the fiber bundle housing 140, and the horizontal linear portion of the fiber bundle housing 140 surrounds a portion of the fiber optic medium 112 that extends from a level above the shaft guide 122 to a level 121. The level above the shaft guide 122 is below the spring stop 138. Moreover the level 121 is along the horizontal direction to the right of the isolation ring nut 164 and to the left of the curved portion of the fiber optic medium 112.

The space 150 extends along the vertical direction and is formed between a portion of the fiber bundle housing 140 and a portion of the shaft guide 122. The space 150 extends along the portion of the fiber bundle housing 140 and surrounds the portion of the fiber bundle housing 140. The shaft guide 122 surrounds a portion of the shaft 116 and the space 150. The space 150 is formed between a bottom surface of the shaft 116 and a bottom surface of the shaft guide 122. The space 150 is adjacent to the shaft 116. The space 150 has a vacuum that extends from the bottom surface of the shaft 116 to the bottom surface the shaft guide 122. In addition, the shaft 116 is located within a vacuum and the vacuum extends until the isolation ring nut 164.

The fiber optic medium 112 extends from the phosphor layer 110 to the isolation ring nut 164. The fiber optic medium 112 has a vertical linear portion extending in the vertical direction from the phosphor layer 110 to the bottom surface of the shaft guide 122, and the vertical linear portion of the fiber optic medium 112 is contiguous with a curved portion of the fiber optic medium 112. The curved portion of the fiber optic medium 112 is located below the shaft guide 122 and the space 150. The curved portion of the fiber optic medium 112 is contiguous with a horizontal linear portion of the fiber optic medium 112. For example, the curved portion of the fiber optic medium 112 is located between the vertical linear portion of the fiber optic medium 112 and the horizontal linear portion of the fiber optic medium 112. The horizontal linear portion of the fiber optic medium 112 extends along the horizontal direction from the curved portion of the fiber optic medium 112 to the isolation ring nut 164.

The isolation ring nut 164 extends along the horizontal direction to surround a portion of another fiber optic medium 127, which is coupled with the fiber optic medium 112. Examples of the fiber optic medium 127 are the same as that of the fiber optic medium 112. Moreover, the connector 172 also extends along the horizontal direction to surround another portion of the fiber optic medium 127. The fiber optic medium 127 is coupled with the temperature probe cable 132.

The temperature sensor probe 102 extends in the horizontal direction within the insulator ring 152. The temperature sensor probe 102 further curves within the insulator ring 152 and extends in the vertical direction via the filler ring 168, the coupling ring 136, and via a portion of the tunable edge ring 106. For example, a through hole in the horizontal direction is fabricated, such as drilled, within the insulator ring 152 to fit a horizontal portion, extending along the horizontal direction, of the temperature sensor probe 102 within the through hole. Moreover, a cable guide is fitted within the through hole within the insulator ring 152 to facilitate a curved portion of the temperature sensor probe 102 to curve within the cable guide. The cable guide extends from the horizontal direction to the vertical direction. Furthermore, the through hole within the insulator ring 152 is formed along the vertical direction to fit a vertical portion of the temperature sensor probe 102. The through hole within the insulator ring 152 extends in the horizontal direction and in the vertical direction. The extension of the through hole of the insulator ring 152 in the horizontal direction is adjacent to the extension of the through hole of the insulator ring 152 in the vertical direction. The cable guide is fitted within a portion of the extension of the through hole of the insulator ring 152 in the vertical direction and within a portion of the extension of the through hole of the insulator ring 152 in the horizontal direction.

In addition, a through hole is formed, such as drilled within the filler ring 168 to vertically extend the temperature sensor probe 102 via the through hole. Furthermore, a through hole is fabricated, such as drilled, within the coupling ring 136 to further vertically extend the temperature sensor by the through hole. In addition, a slot is fabricated, such as drilled, within the bottom surface of the tunable edge ring 106 or edge ring 108 to insert the thermally conductive layer 104 within the slot.

As temperature of the edge ring 108 or the tunable edge ring 106 or the heater changes, such as increases or decreases, a temperature of the thermally conductive layer 104 changes, such as increases or decreases. With the change in the temperature of the thermally conductive layer 104 and when light from a light source is incident on the phosphor layer 110, a temperature of the phosphor layer 110 changes and the phosphor layer 110 emits light. The light source emits light towards the phosphor layer 110 via the fiber optic medium 112. The light emitted by the phosphor layer 110 as a result of the light incident on the phosphor layer 110 travels via the fiber optic medium 112 in the vertical direction, such as a downward direction, further along the curved portion of the fiber optic medium 112 and further along the horizontal linear portion of the fiber optic medium 112. The light further travels from the horizontal portion of the fiber optic medium 112 via the fiber optic medium 127, a portion of which is in the isolation ring nut 164, to be received by the temperature probe cable 132. The temperature probe cable 132 further transfers the light to the converter 130, which converts the light into an electrical signal. The processor of the temperature controller 134 receives the electrical signal and from a rate of change in intensity of the electrical signal, determines a temperature of the heater or the edge ring 108 or the tunable edge ring 106 or the heater. For example, the processor determines the temperature based on an amount of time it takes for the intensity of the electrical signal to reach a pre-determined level. The intensity of the electrical signal diminishes from a level that is measured by the phosphor layer 110 to the pre-determined level.

The processor of the temperature controller 134 sends a control signal to a power supply, such as a direct current (DC) power supply, that is coupled to the heater. Upon receiving the control signal, the power supply modifies such as increases or decreases, an amount of power being supplied to the heater by the power supply to change a temperature within the plasma chamber.

In some embodiments, the temperature sensor probe 102 excludes the connector 172 and the isolation ring nut 164.

In various embodiments, the fiber optic medium 112 is a fiber optic tube. The fiber optic tube cannot be curved and is straight.

In various embodiments, the shaft 116 is not made from a thermally conductive material, such as aluminum or steel or another metal, which is highly conductive to heat transferred from the thermally conductive layer 104. As a thermal conductance to the thermal conductivity material of the shaft 116 increases, accuracy of temperature that is measured by the phosphor layer 110 decreases.

In several embodiments, the curved portion, as used herein, of the temperature sensor probe 102 is an arced portion that has a radius.

In some embodiments, the thermally conductive layer 104 is in contact with a heater embedded within the tunable edge ring 106.

In various embodiments, the phosphor layer 110 is sometimes referred to herein as a luminescent layer or a temperature sensing layer.

In some embodiments, instead of the luminescent fluoroptic tip, a thermocouple, a thermister, or an Inter-integrated circuit (I²C) chip is used to measure a temperature within the plasma chamber. The luminescent fluoroptic tip, the thermocouple, the thermister, and the I²C chip are all examples of a temperature sensing medium. It should be noted that when the thermocouple, thermister, or the I²C chip is used, instead of light emitted from the phosphor layer 110, an electrical signal is generated based on a temperature within the plasma chamber. The electrical signal is transferred via a metal conductor, such as an electrically conductive wire, to the temperature controller 134. The conductor and a fiber optic medium are examples of a temperature signal-carrying medium. The electrical signal and the light emitted from the luminescent fluoroptic tip are examples of a temperature signal.

FIG. 1B is a diagram of an embodiment of the temperature sensor probe 102. The shaft guide 122 extends in the vertical direction to fit over the shaft 116. Once the shaft guide 122 is extended over the shaft 116, the spring 162 is extended in the vertical direction to abut the shaft guide 122. Once the spring 162 abuts the shaft guide 122, the spring stop 138 is extended in the vertical direction to abut the spring 162.

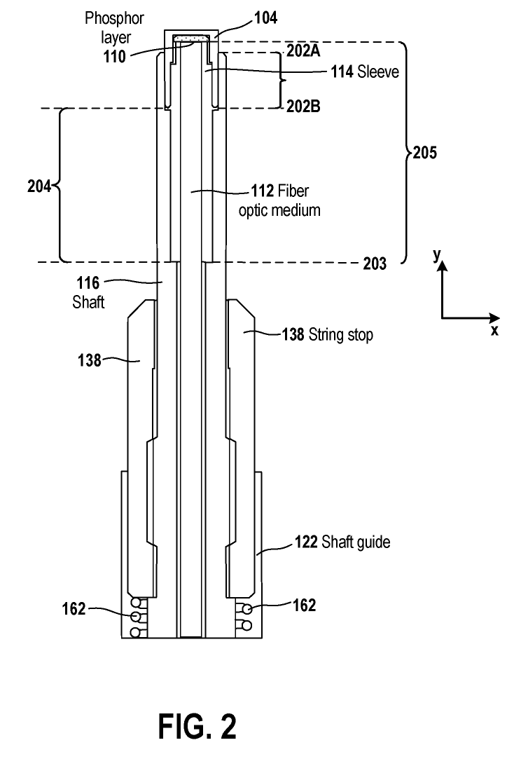

FIG. 2 is a diagram of an embodiment of a portion of the temperature sensor probe 102. This sleeve 114 extends in the vertical direction over a portion 205 of the fiber optic medium 112 to surround the portion 205. The portion 205 of the fiber optic medium 112 is a part of a distal end of the fiber optic medium 112. The distal end of the fiber optic medium 112 is further described below. The portion 205 is between the bottom surface of the phosphor layer 110 and a level 203. The level 203 is above the spring stop 138. The level 203 is between the spring stop 138 and the thermally conductive layer 104.

The shaft 116 extends in the vertical direction parallel to a portion 202 of the thermally conductive layer 104 to surround the portion 202 of the thermally conductive layer 104. For example, a portion of an inner surface of the shaft 116 is adjacent to the portion 202 of an outer surface of the thermally conductive layer 104. The portion 202 extends from a level 202A below the phosphor layer 110 until a level 202B below the phosphor layer 110. The level 202A is above the level 202B.

Moreover, the shaft 116 further extends in the vertical direction over a portion 204 of the sleeve 114 to surround the portion 204 of the sleeve 114. For example, a portion of the inner surface of the shaft 116 is adjacent to the portion 204 of an outer surface of the sleeve 114. The portion 204 extends from a bottom surface of the thermally conductive layer 104 to the level 203. Because the shaft 116 extends in the vertical direction to surround the portion 202 of the thermally conductive layer 104 and the portion 204 of the sleeve 114, the shaft 116 reduces chances, such as protects, the portions 202 and 204 from being corroded by the one or more process gases.

The sleeve 114 protects the fiber optic medium 112 from being damaged during manufacturing of the temperature sensor probe 102. The sleeve 114 is made from plastic instead of glass. If sleeve 114 is made from glass, then the glass sleeve may fracture when the temperature sensor probe 102 is bent. The temperature sensor probe 102 is more susceptible to bending when the shaft 122 is made from a less rigid material such as PFA or PTFE instead of a harder or a more rigid material such as Torlon™.

In some embodiments, in which the shaft 116 is made from the rigid material, the sleeve 114 is made from glass and the glass sleeve 114 is bonded to the ceramic. For example, a silicone adhesive is used to attach, such as bond, the glass sleeve 114 with the ceramic shaft 116. The rigid material is not flexible in that the rigid material is stiff compared to the flexible material. For example, a force used to bend the rigid material is substantially greater than a force used to bend the flexible material.

In various embodiments, a non-resistive material, such as polyamide-imide or acrylonitrile butadiene styrene (ABS), is not used for fabricating the shaft 116. The non-resistive material offers lower or no resistance to corrosion compared to the materials described above for fabricating the shaft 116. Teflon™ is an example of polyamide-imide. Polyamide-imide is rigid and is not flexible. Moreover, polyamide-imide has an etch resistance that is less than that of the materials listed above for fabricating the shaft 116. For example, when polyamide-imide is used to protect a temperature probe, a number of active processing hours for which the temperature probe is used within the plasma chamber is less than about 1000 hours. As another example, when polyamide-imide is used to protect a temperature probe, a number of active processing hours for which the temperature probe is used within the plasma chamber is less than about 1200 hours. As yet another example, when polyamide-imide is used to protect a temperature probe, a number of active processing hours for which the temperature probe is used within the plasma chamber is less than about 2000 hours. As yet another example, when polyamide-imide is used to protect a temperature probe, a number of active processing hours for which the temperature probe is used within the plasma chamber ranges from and including about 1500 active processing hours to about 2000 active processing hours. Fifteen hundred active processing hours corresponds to a time period of about 3 months and 2000 active processing hours corresponds to a time period of about 4 months. For example, when the temperature sensor probe 102 or the temperature probe is used for about 3 months, the temperature sensor probe 102 or the temperature probe is within the plasma chamber for about 1500 active processing hours. As another example, when the temperature sensor probe 102 or the temperature probe is used for about 4 months, the temperature sensor probe 102 or the temperature probe is within the plasma chamber for about 2000 active processing hours.

Moreover, it should be noted that an annular width of the shaft 116 is reduced by about a 100^{th} compared to a reduction in an annular width of the polyamide-imide when used as a protective medium of the temperature probe. For example, the annular width of polyamide-imide when used as the protective medium for the temperature probe decreases by about 0.02 inch after one mean time between clean (MTBC) of the plasma chamber. The shaft 116 has the annular width that is reduced by about 0.0002 inch after one MTBC. The annular width of the shaft 116 is a difference between an inner diameter of the inner surface of the shaft 116 and an outer diameter of an outer surface of the shaft 116. It should be noted that the inner diameter and the outer diameter of the shaft 116 are variable along a length of the shaft 116. The length of the shaft 116 is along the y-axis and the inner and outer diameters are along the x-axis.

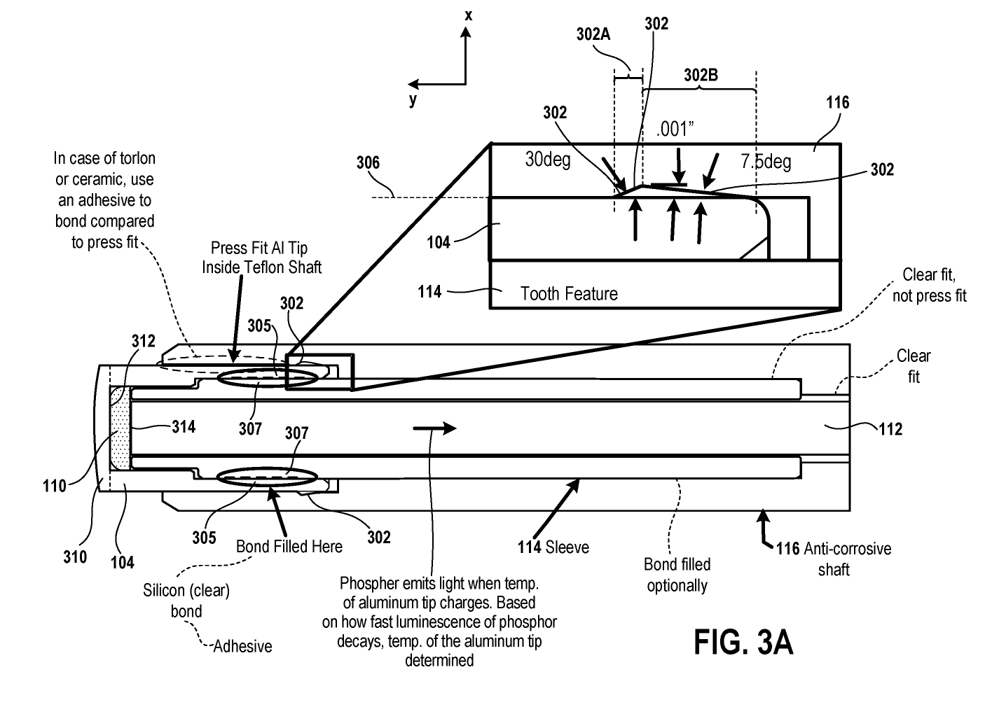

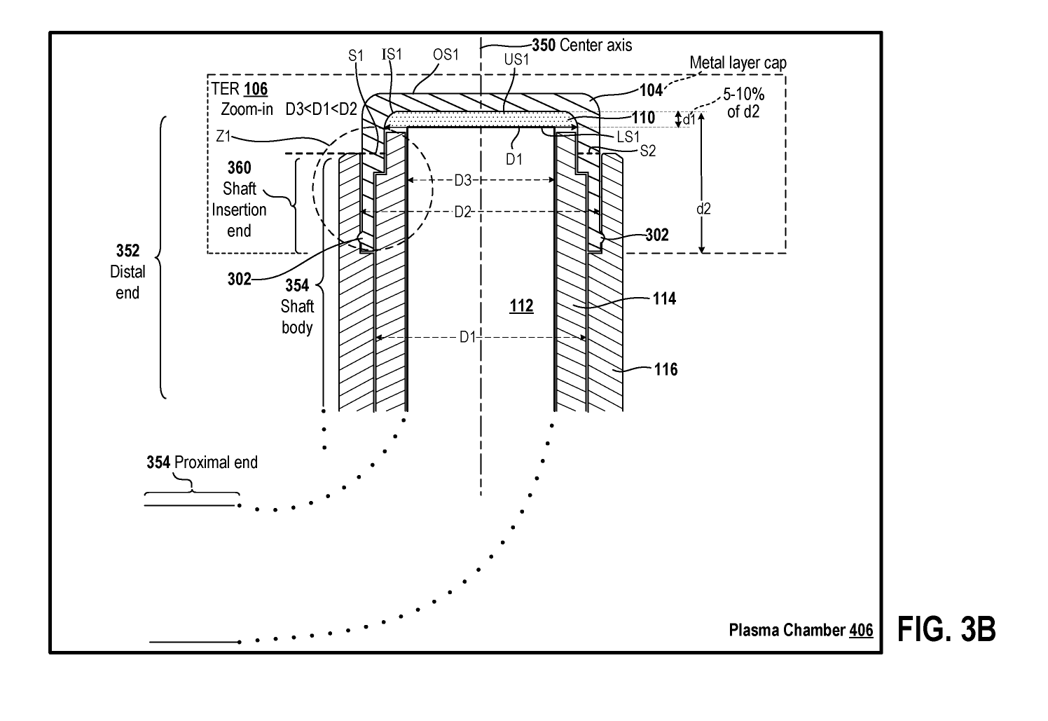

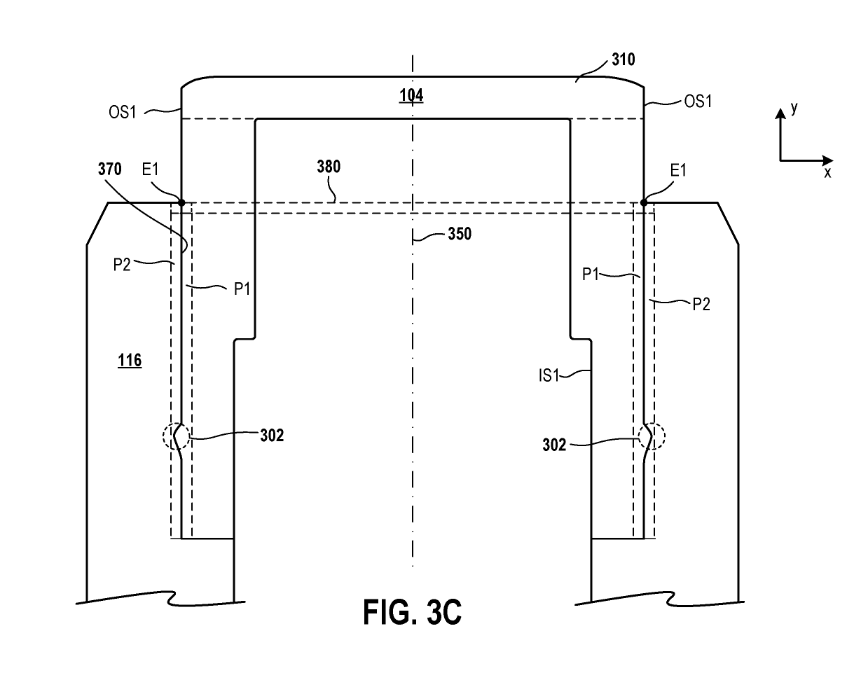

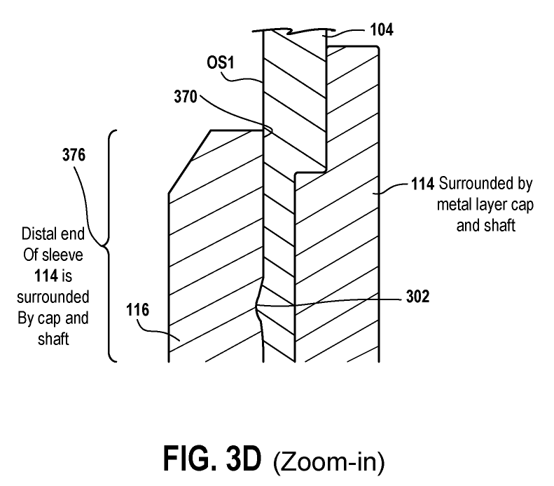

FIG. 3A is a diagram of an embodiment of a portion of the temperature sensor probe 102. The thermally conductive layer 104 has a tip 310. A bottom surface 312 of the tip 310 is in contact with an upper surface of the phosphor layer 110. Moreover, a bottom surface 314 of the phosphor layer 110 abuts to, such as in contact with, the fiber optic medium 112.

The outer surface of the thermally conductive layer 104 has an extended feature 302. For example, the extended feature 302 is integrated within the outer surface of the thermally conductive layer 104. As another example, the extended feature is integrated within the thermally conductive layer 104 to circle around a body of the thermally conductive layer 104. The outer surface of the thermally conductive layer 104 faces the inner surface of the shaft 116. For example, a portion of the outer surface of the thermally conductive layer 104 is adjacent to a portion of the inner surface of the shaft 116. The extended feature 302 is sometimes referred to herein as a tooth feature. The extended feature 302 extends in the horizontal direction with respect to a vertical plane along a length of the thermally conductive layer 104. The length of the thermally conductive layer 104 is along the y-axis. Each vertical plane, described herein, is parallel to the y-axis. The extended feature 302 is made from the same material from which the thermally conductive layer 104 is made. It should be noted that the extended feature 302 is not retractable in the horizontal direction.

The extended feature 302 has a portion 302A and another portion 302B. The portion 302A forms an angle of about 30 degrees with respect to the vertical plane 306 along the length of the outer surface of the thermally conductive layer 104. For example, the portion 302A forms an angle ranging from and including about 20° to about 32° with respect to the vertical plane 306. Moreover, the portion 302B forms an angle of about 7.5° with respect to the vertical plane 306. For example, the portion 302B forms an angle from including about 7° to about 8° with respect to the vertical plane 306. The vertical plane 306 extends in the vertical direction and is parallel to the vertical direction. Furthermore, a thickness of the extended feature 302 along the horizontal direction is about 0.001 inch. For example, the thickness of the extended feature 302 ranges from including about 0.0005 inch to about 0.0015 inch. The thickness of the extended feature 302 is measured in the horizontal direction from the vertical plane 306.

The thermally conductive layer 104 is inserted between the sleeve 114 and the shaft 116 in the vertical direction until the extended feature 302 fits against the shaft 116 to press fit the high thermally conductive layer 104 to the shaft 116. The press fit reduces chances of, such as prevents the one or more process gases within the plasma chamber from entering between the outer surface of the thermally conductive layer 104 and the inner surface of the shaft 116 to protect the shaft 116 and the fiber optic medium 112 from corrosion. Moreover, the press fit reduces chances of the thermally conductive layer 104 from falling off from between the shaft 116 and the sleeve 114 during handling or maintenance or manufacturing of the temperature sensor probe 102 or removal of the temperature sensor probe 102 from the plasma chamber. For example, the extended feature 302 makes it more difficult to pull out in the vertical direction the thermally conductive layer 104 from between the shaft 116 and the sleeve 114 compared to pushing the thermally conductive layer 104 in the vertical direction to fit between the shaft 116 and the sleeve 114. As such, the extended features 302 provides a retention force to retain a position of the thermally conductive layer 104 with respect to a position of the shaft 116. It should be noted that when ceramic is used as a material for the shaft 116, instead of press fitting the thermally conductive layer 104 to the shaft 116, a bond is formed via an adhesive, such as a silicone adhesive, between the shaft 116 and the thermally conductive layer 104.

Moreover, the thermally conductive layer 104 is attached, such as bonded via silicone adhesive, with an outer surface of the sleeve 114. For example, a portion 305 of the inner surface of the thermally conductive layer 104 is bonded with a portion 307 of the outer surface of the sleeve 114. thermally conductive layer

It should be noted that the shaft 116 is fabricated, such as machined, using a lathe machine. Furthermore, the shaft 116 is clearance fitted to the sleeve 114. For example, and there is no bond, such as adhesive bond, formed between a portion of the inner surface of the shaft 116 and a portion of the outer surface of the sleeve 114. The portion of the inner surface of the shaft 116 is adjacent to the portion of the outer surface of the sleeve 114 and the adhesive bond is not formed between the two portions.

The phosphor layer 110 emits light when excited by light generated by the light source. The light travels via the cable 132, the fiber optic medium 127, and the fiber optic medium 112 to the phosphor layer 110. The rate of decay of the light emitted from the phosphor layer 110 changes with respect to temperature of the phosphor layer 110. The temperature of the phosphor layer 110 changes when heated due to a temperature within the plasma chamber, such as the temperature of the heater within the tunable edge ring 106 (FIG. 1A), or the temperature of the edge ring 108 (FIG. 1A). When temperature of the phosphor layer 110 changes, the phosphor layer 110 emits light. The light that is emitted by the phosphor layer 110 travels via the fiber optic medium 112 and the fiber optic medium 127 to the temperature probe cable 132 (FIG. 1A) for being converted by the converter 130 (FIG. 1A). The converter 130 converts the light into the electrical signal. The processor of the temperature controller 134 (FIG. 1A) determines a rate of decrease in amplitude of the electrical signal until the pre-determined level is reached to further determine a temperature that is measured by the temperature sensor probe 102.

The shaft 116 excludes fillers, such as, titanium dioxide or titanium, which are present in Torlon™. When Torlon™ corrodes due to the one or more process gases, a mixture of the fillers and the one or more process gases generates a contaminant material, such as titanium fluoride, that contaminates the plasma chamber. The contamination of the plasma chamber negatively affects processing of the substrate within the plasma chamber. With use of the shaft 116 that is not made from Torlon™, chances of corrosion of the shaft 116 are diminished. The shaft 116 excludes the fillers. So, there is no generation of the contaminating material when the shaft 116 is used within the plasma chamber for processing the substrate.

In some embodiments, when the thermally conductive layer 104 is press fitted with the shaft 116, there is no adhesive bond formed between the thermally conductive layer 104 and the shaft 116.

In several embodiments, an adhesive bond, such as a bond formed using a silicone adhesive, is formed between the adjacent portions of the inner surface of the shaft 116 and of the outer surface of the sleeve 114.

In various embodiments, there is no adhesive bond formed between the outer surface of the thermally conductive layer 104 and the inner surface of the shaft 116.

FIG. 3B is a diagram of an embodiment of a plasma chamber 406 to illustrate a cross-section of the temperature sensor probe 102. The phosphor layer 110 has an upper surface US1 and a lower surface LS1. Each of upper surface US1 and lower surface LS1 is oriented in the horizontal direction. The upper surface US1 is adjacent to, such as next to and in contact with, a portion of an inner surface IS1 of the thermally conductive layer 104. For example, the upper surface US1 is in contact with and faces the inner surface IS1 of the thermally conductive layer 104. The lower surface LS1 is not in contact with the inner surface IS1 of the thermally conductive layer 104. As an example, the inner surface IS1 is along the inverted U-shape of the thermally conductive layer 104. The phosphor layer 110 has a distance d1, which is along a center axis 350. The center axis 350 is further described below.

The thermally conductive layer 104 has an outer surface OS1. As an example, the outer surface OS1 is along the inverted U-shape of the thermally conductive layer 104. The inner surface IS1 is closer to the phosphor layer 110 compared to the outer surface OS1 Moreover, the outer surface OS1 is not adjacent to the phosphor layer 110.

The fiber optic medium 112 has the center axis 350 that passes via a centroid of the vertical linear portion of the fiber optic medium 112. As an example, the center axis 350 is parallel to the y-axis. The vertical linear portion of the fiber optic medium 112 is parallel to the center axis 350.

The shaft 116 has a shaft body 362 further having a shaft insertion end 360. The shaft insertion end 360 extends along the center axis 350 from the bottom surface of the thermally conductive layer 104 to a level located, in the vertical direction, between the extended feature 302 and a top surface of the sleeve 114.

The fiber optic medium 112 has a distal end 352 that is closer to the phosphor layer 110 compared to a proximal end 354 of the fiber optic medium 112. Moreover, the distal end 352 is adjacent to, such as next to and in contact with, the lower surface LS1 of the phosphor layer 110. The proximal end 354 is the horizontal linear portion of the fiber optic medium 112 and the distal end 352 is a vertical linear portion of the fiber optic medium 112. The proximal end 354 facilitates a transfer of light that is emitted by the phosphor layer 110 and received via the vertical linear portion and the curved portion of the fiber optic medium 112 to the cable 132 (FIG. 1A). The curved portion of the fiber optic medium 112 is between the proximal end 354 and the distal end 352.

The fiber optic medium 112 has a diameter D3, which is substantially uniform along the vertical linear portion, the curved portion, and the horizontal linear portion of the fiber optic medium 112. Moreover, an outer diameter of the sleeve 114 is D1. For example, a diameter of the outer surface of the sleeve 114 is D1. A portion of the outer surface of the sleeve 114 is adjacent to a portion of the inner surface IS1 of the thermally conductive layer 104 and a portion of the outer surface of the sleeve 114 is adjacent to the inner surface of the shaft 116. The diameter D3 is less than the diameter D1.

Moreover, the outer surface OS1 of the thermally conductive layer 104 has a diameter D2. Each diameter D1, D2, and D3 is measured along the horizontal direction. The diameter D2 is greater than the diameter D1.

A distance d2 is defined between the upper surface US1 of the phosphor layer 110 and the bottom surface of the thermally conductive layer 104. The distance d2 is parallel to the center axis 350. The distance d1 of the phosphor layer 110 is less than the distance d2. For example, a thickness of the phosphor layer 110, measured along the center axis 350, is less than the distance d2. As another example, the distance d1 is between about 5% and about 10% of the distance d2.

FIG. 3C is a cross-section of an embodiment of a portion of the temperature sensor probe 102. A portion of an inner surface 370 of the shaft 116 is adjacent to, such as next to and in contact with, the outer surface OS1 of the thermally conductive layer 104. The extended feature 302, which is a protrusion from the outer surface OS1 of the thermally conductive layer 104 extends into the shaft 116 to form a press fit with the portion of the inner surface 370 of the shaft 116. It should be noted that in some embodiments, the press fit is formed without the extended feature 302 extending into any slot within the inner surface 370. For example, there is no slot within the inner surface 370 for the extended feature 302 to extend into.

The outer surface OS1 of the thermally conductive layer 104 has a portion P1. Moreover, the inner surface 370 has a portion P2. Each portion P1 and P2 is oriented in and extends in the vertical direction along the center axis 350. The tip 310 of the thermally conductive layer 104 is located above the portions P1 and P2. The shaft 116, when press fitted with the outer surface OS1 of the thermally conductive layer 104 via the extended feature 302 creates a corrosion seal between the portions P1 and P2. For example, the corrosion seal is created in a peripheral region 380. The peripheral region 380 is a region that covers an edge E1, of the shaft 116, having an inner diameter, portions of each of the portions P1 and P2, and a portion of the outer surface OS1. The peripheral region 380 extends in the horizontal direction along the portion of the outer surface OS1 and the edge E1 is adjacent to, such as in contact with, the portion. The peripheral region 380 has a circular cross-section in the vertical direction of the y-axis. The portions P1 and P2 are adjacent, such as next to and in contact with the edge E1 of the shaft 116. The corrosion seal reduces chances of, such as avoids or prevents, plasma formed within the plasma chamber or of contaminant materials formed within the plasma chamber to enter between the portions P1 and P2. As such, the fiber optic medium 112 is isolated from plasma chemistries, such as the one or more process gases, or the contaminant materials, by the corrosion seal.

It should be noted that the tip 310 of the thermally conductive layer 104 is exposed to, such as in contact with, the heater, the edge ring 108, or the tunable edge ring 106 (FIG. 1A) to interface with the heater, the edge ring 108, or the tunable edge ring 106. The contact between the tip 310 and the heater, the edge ring 108, or the tunable edge ring 106 allows temperature of the heater, the edge ring 108, or the tunable edge ring 106 to be measured by the tip 310.

FIG. 3D is a cross-section of an embodiment of a portion of the temperature sensor probe 102. The portion is a zoom-in view Z1 (FIG. 3B) of the temperature sensor probe 102. When the extended feature 302 press fits to the shaft 116, a portion of the outer surface OS1 of the thermally conductive layer 104 is sealed with respect to a portion of the inner surface 370 of the shaft 116 to prevent plasma or remnants of a process performed on the substrate from entering between the outer surface OS1 and the inner surface IS2 of the shaft 116. Moreover, it should be noted that a distal end 376 of the sleeve 114 is surrounded by a portion of the thermally conductive layer 104 and a portion of the shaft 116. The distal end 376 of the sleeve 114 is closer to the phosphor layer 110 than a proximal end of the sleeve 114. It should be noted that the proximal end of the sleeve 114 is any remaining portion of a body of the sleeve 114 other than the distal end of the sleeve 114.

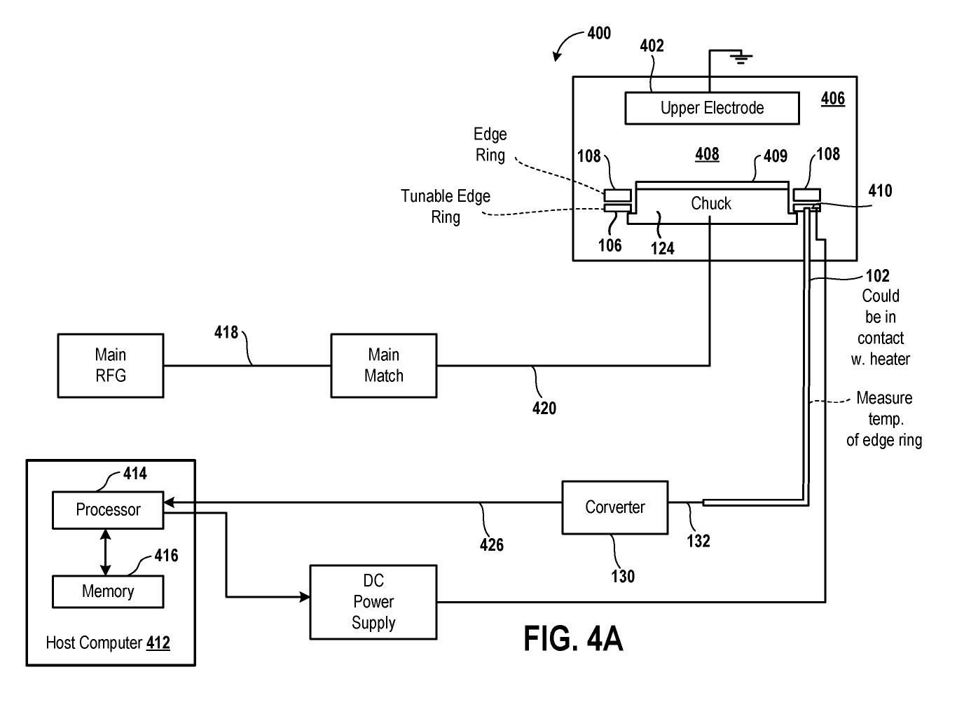

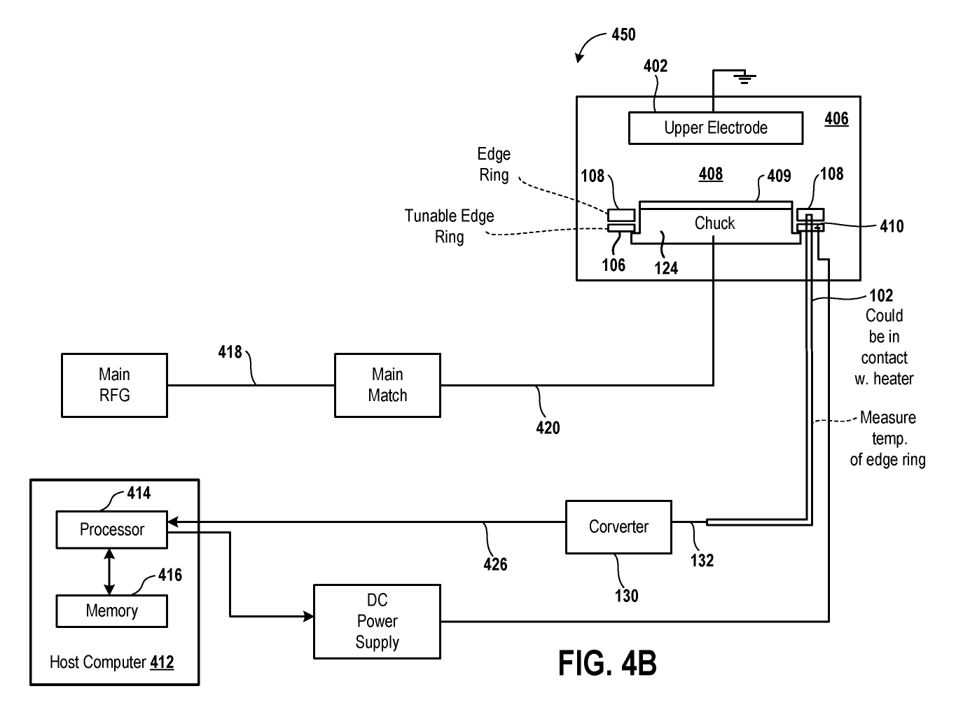

FIG. 4A is a diagram of an embodiment of a system 400 to illustrate use of the temperature sensor probe 102 that extends via the bottom surface of the tunable edge ring 106 with a plasma chamber 406. The temperature sensor probe 102 extends via the bottom surface of the tunable edge ring 106 to extend within the slot formed in the bottom surface.

The plasma chamber 406 includes the edge ring 108 and the tunable edge ring 106. The system 400 includes a main radio frequency (RF) generator (RFG), a main match the plasma chamber 406, and a host computer 412. Examples of the host computer, described herein, include a desktop computer, a laptop computer, a tablet, and a smart phone. The temperature controller 134 (FIG. 1A) is an example of the host computer 412.

The host computer 412 includes a processor 414 and a memory 416, e.g., a random access memory (RAM), a read-only memory (ROM), a volatile memory, a non-volatile memory, etc. The processor 414 is coupled to the memory 416. As used herein, a processor is an application specific integrated circuit (ASIC), or a programmable logic device (PLD), or a microprocessor, or a microcontroller, or a central processing unit (CPU), and these terms are used interchangeably herein. Examples of a memory device, as used herein, include a Flash memory, a hard disk, etc.

The plasma chamber 406 includes an upper electrode 402, the chuck 124, the tunable edge ring 106, the edge ring 108, and a substrate 409. The substrate 409 is placed on a top surface of the chuck 124. Integrated circuits, e.g., an ASIC, a PLD, etc., are developed on the substrate 409 and the integrated circuits are used in a variety of devices, e.g., cell phones, tablets, smart phones, computers, laptops, networking equipment, etc. The upper electrode 402 is made from silicon. The upper electrode 402 faces the chuck 124. The edge ring 108 surrounds a portion of the chuck 124. Moreover, the tunable edge ring 106 surrounds a portion of the chuck 124.

The main RF generator is coupled to the main match via an RF cable 418 and the main match is coupled to the chuck 124 within plasma chamber 406 via an RF transmission line 420. An example of the RF transmission line 420 is an RF cable that is coupled to an RF rod, which is coupled to a lower electrode within the chuck 124. The processor 414 is coupled to a controller, such as a digital signal processor, within the main RF generator. Moreover, the processor 414 is coupled to the converter 130 via a data transfer cable 426, such as a serial transfer cable, a parallel transfer cable, or a universal serial bus (USB) cable. Each RF generator, described herein, includes a processor and an RF power supply, such as an RF oscillator. The processor is coupled to the RF power supply of the main RF generator.

A match, described herein, is an impedance matching network or an impedance matching circuit that includes electric circuit components, e.g., inductors, capacitors, etc. to match an impedance of a load coupled to an output of the match with an impedance of a source coupled to the input of the match. For example, the main match matches an impedance of the plasma chamber 406 and the RF transmission line 420 coupled to the output of the main match with an impedance of the main RF generator and the RF cable 418.

The processor 414 sends a control signal to the main RF generator The control signal sent to the main RF generator has frequency and power of operation of the main RF generator. Upon receiving the control signal, the main RF generator generates a main RF signal having the frequency and power and sends the main RF signal via the RF cable 418 to the main match. The main match matches an impedance of the load coupled to the output of the main match with that of the source coupled to the input of the main match to modify the main RF signal to generate a modified main RF signal and sends the modified main RF signal via the RF transmission line 420 to the chuck 124.

When one or more process gases are supplied to a gap 408 between the upper electrode 402 and the chuck 124 in addition to supplying the modified main RF signal to the lower electrode of the chuck 124, plasma is stricken or maintained within the gap 408 to process the substrate 409. For example, the substrate 409 is processed by using the plasma to deposit material on the substrate, etch the substrate, clean the substrate, or sputter the substrate. Examples of the one or more process gases include an oxygen-containing gas, such as O₂. Other examples of the one or more process gases include a fluorine-containing gas, such as, tetrafluoromethane (CF₄), sulfur hexafluoride (SF₆), or hexafluoroethane (C₂F₆).

During processing of the substrate 409, temperature within the plasma chamber 406, such as the temperature of the tunable edge ring 106, or the temperature of a heater 410 within the tunable edge ring 106, or the temperature of the edge ring 108, is measured by the phosphor layer 110 (FIG. 1) of the temperature sensor probe 102 (FIG. 1). A temperature sensor signal having the measured temperature is sent via the temperature probe cable 132 (FIG. 14A) to the processor 414. The processor 414 determines the measured temperature from the temperature sensor signal and controls the power supply, such as the direct current (DC) power supply, to change an amount of power that is being supplied to the heater 410, such as a resistor, embedded within the tunable edge ring 106 to change a temperature within the plasma chamber 406.

In some embodiments, the chuck 124 is coupled to the ground potential and the upper electrode 402 is coupled to the main RF generator via the main match.

FIG. 4B is a diagram of an embodiment of a plasma system 450 to illustrate use of the temperature sensor probe 102 that extends within the edge ring 108. For example, the temperature sensor probe 102 extends via a through hole within the tunable edge ring 106 to further extend within a slot formed in a bottom surface of the edge ring 108. Moreover, the heater 410 is embedded within the tunable edge ring 106. The remaining structure and function of the system 450 is the same as that of the system 400 of FIG. 4A.

It should be noted that although the temperature sensor probe 102 is implemented within a dielectric etch chamber as illustrated in FIG. 4A and 4B, in some embodiments, the temperature sensor probe 102 is implemented within an inductively coupled plasma (ICP) chamber, or an ion implantation chamber, or a plasma deposition chamber, or any other chamber that uses a liquid or a gas, which corrodes a temperature sensing device.

It should be noted that although the above embodiments are described with respect to the plasma chamber, it should be noted that in some embodiments, the temperature sensor probe 102 is implemented in a chamber, such as a liquid deposition or gas deposition chamber, that is not a plasma chamber. For example, in the liquid deposition chamber, a liquid may be sprayed onto a substrate to deposit materials on the substrate or to etch portions of the substrate or to clean the substrate. As another example, a gas is supplied to a gas chamber to deposit materials on the substrate or to etch portions of the substrate or to clean the substrate.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of the one or more process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma ion implantation chamber, a plasma deposition chamber, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer- readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A sensor probe for measuring a temperature of a structure, comprising:
a thermally conductive cap having an outer surface and an inner surface;
a temperature sensing medium having an upper surface and a lower surface, the upper surface is disposed adjacent to a portion of the inner surface of the thermally conductive cap;
a temperature signal-carrying medium oriented along a vertical axis, wherein a distal end of the temperature signal-carrying medium is oriented adjacent to the lower surface of the temperature sensing medium and a proximal end of the temperature signal-carrying medium is configured to carry a temperature signal detected during measuring of said temperature;
a sleeve that extends over and surrounds a portion of the temperature signal- carrying medium near the distal end; and
a shaft that extends over and surrounds a portion of the thermally conductive cap, a portion of the sleeve and a portion of the temperature signal-carrying medium that is not surrounded by the sleeve along the vertical axis;
wherein the shaft provides a corrosion seal around sides of the thermally conductive cap and isolates the temperature signal-carrying medium from corrosive chemistries during operation of a chamber,
wherein a top portion of the outer surface of the thermally conductive cap is exposed to enable positional interface of said sensor probe with said structure.

2. The sensor probe of claim 1, wherein the shaft is made from a material that is usable for an amount of active processing hours between about 2100 and about 7500.

3. The sensor probe of claim 2, wherein the shaft is made from a corrosion-resistant material that has a greater resistance to corrosion compared to that of a non-resistant material and the corrosion-resistant material has a thermal conductivity of less than about five watts per meter Kelvin to sustain a temperature of the thermally conductive cap.

4. The sensor probe of claim 3, wherein the non-resistant material is polyamide-imide or acrylonitrile butadiene styrene (ABS).

5. The sensor probe of claim 3, wherein the corrosion-resistant material is perfluoroalkoxy (PFA), or polytetrafluoroethylene (PTFE), or zirconia, or quartz, or mullite, or steatite, or cordierite.

6. The sensor probe of claim 1, when the thermally conductive cap is press fitted to the shaft to increase manufacturability and corrosion resistance of the sensor probe.

7. The sensor probe of claim 1, wherein the outer surface of the thermally conductive cap is associated with an extended portion to provide a retention force of the thermally conductive cap with respect to the shaft, wherein the extended portion extends in a horizontal direction from a vertical plane along a length of the thermally conductive cap.

8. The sensor probe of claim 1, wherein the thermally conductive cap is bonded with the sleeve.

9. The sensor probe of claim 1, wherein there is a lack of an adhesive bond between the thermally conductive cap and the shaft and between the sleeve and the shaft.

10. The sensor probe of claim 1, wherein the shaft is adjacent to the portion of the thermally conductive cap, the portion of the sleeve, and the portion of the temperature signal-carrying medium near the distal end.

11. The sensor probe of claim 1, wherein a fabrication material for the thermally conductive cap includes a corrosion-resistant material.

12. The sensor probe of claim 11, wherein the corrosion-resistant material for the thermally conductive cap is aluminum, or aluminum nitride, or copper.

13. The sensor probe of claim 1, wherein the temperature sensing medium is a luminescent fluoroptic tip, or a thermocouple, or a thermistor, or an I2C chip, and wherein the temperature signal-carrying medium is an optical fiber or an electrically conductive wire.

14. A system for measuring a temperature of a structure, comprising:
a substrate support configured to support a substrate;
a ring surrounding the substrate support;
a sensor probe associated with the ring, wherein the sensor probe includes:
a thermally conductive cap having an outer surface and an inner surface;
a temperature sensing medium having an upper surface and a lower surface, the upper surface is disposed adjacent to a portion of the inner surface of the thermally conductive cap;
a temperature signal-carrying medium oriented along a vertical axis, wherein a distal end of the temperature signal-carrying medium is oriented adjacent to the lower surface of the temperature sensing medium and a proximal end of the temperature signal-carrying medium is configured to transfer a temperature signal detected during measuring of said temperature of said structure;
a sleeve that extends over and surrounds a portion of the temperature signal- carrying medium near the distal end; and
a shaft that extends over and surrounds a portion of the thermally conductive cap, a portion of the sleeve, and a portion of the temperature signal-carrying medium that is not surrounded by the sleeve along the vertical axis;
wherein the shaft provides a corrosion seal around sides of the thermally conductive cap and isolates the temperature signal-carrying medium from materials during operation of the system,
wherein a top portion of the outer surface of the thermally conductive cap is exposed to enable positional interface of said sensor probe with the ring.

15. The system of claim 14, wherein the shaft is made from a material that is usable for an amount of active processing hours between about 2100 and about 7500.

16. The system of claim 14, wherein the shaft is made from a corrosion-resistant material that has a greater resistance to corrosion compared to that of a non-resistant material and the corrosion-resistant material has a thermal conductivity of less than about five watts per meter Kelvin to sustain a temperature of the thermally conductive cap.

17. The system of claim 16, wherein the corrosion-resistant material is perfluoroalkoxy (PFA), or polytetrafluoroethylene (PTFE), or zirconia, or quartz, or mullite, or steatite, or cordierite.

18. The system of claim 14, when the thermally conductive cap is press fitted to the shaft.

19. The system of claim 14, wherein the outer surface of the thermally conductive cap has an extended portion to provide a retention force of the thermally conductive cap with respect to the shaft, wherein the extended portion extends in a horizontal direction with respect to a vertical plane along a length of the thermally conductive cap.

20. The system of claim 14, wherein the ring is an edge ring, wherein a temperature of the edge ring is monitored using the temperature signal detected by the sensor probe.

21. The system of claim 14, wherein the ring is a tunable edge ring, wherein a temperature of the tunable edge ring is controlled using the temperature signal generated by the sensor probe.
